(19) United States
(12) Patent Application Publication
(10) Pub. No.: US 2008/0101037 A1
(43) Pub. Date: May 1, 2008

(54) Securing object relative to PC board using retention device attached to surface-mounted attachment mechanisms

(76) Inventors: Thom Augustin, El Dorado Hills, CA (US); Lidia Warnes, Sacramento, CA (US); Gary King Chan, Palo Alto, CA (US); Ricardo Ernesto Espinoza-Ibarra, Lincoln, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/590,734

(22) Filed: Oct. 31, 2006

(51) Int. Cl. H05K 7/20

(52) U.S. Cl. 361/720

(57) ABSTRACT

Attachment mechanisms are surface-mounted to a PC board. An object is secured relative to said PC board by a retention device attached to the attachment mechanisms.

### BACKGROUND OF THE INVENTION

Herein, related art may be discussed to put the invention in context. Related art labeled “prior art” is admitted prior art; related art not labeled “prior art” is not admitted prior art.

Many components of printed-circuit (PC) boards such as microprocessors and voltage regulators generate heat during operation. Heat can damage devices, impair their performance, and create a fire or explosive hazard. Heat sinks can be used to conduct and radiate heat from a device. A thermal adhesive can be used to affix the heat sink to the device, but this can be problematic for disassembly. To allow for disassembly, thermally conductive paste can be applied between the device and heat sink and a clamping mechanism or screws can be used to hold the heat sink against the device.

The screws or clamping mechanism typically require holes to be drilled through the PC board. The various conductors in the layers of the PC board must be routed around where the holes are to be formed. The present invention addresses this constraint on PC board conductor layouts. These and other features of the present invention are apparent from the description below with reference to the following drawings.

### BRIEF DESCRIPTION OF THE DRAWINGS

The following drawings are of an embodiment of the invention and not of the invention itself.

FIG. 1 is a schematic diagram of a computer having a heat sink mounted on a processor in accordance with an embodiment of the present invention.

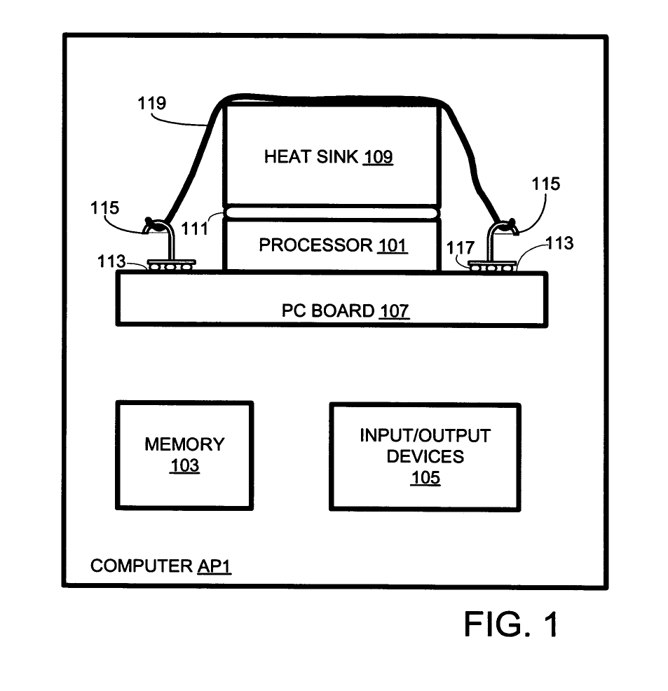

FIG. 2 is a schematic perspective drawing of a hook used to hold the heat sink of FIG. 1 in place.

FIG. 3 is a flow chart of a method for assembling the structure of FIG. 1 in accordance with an embodiment of the invention.

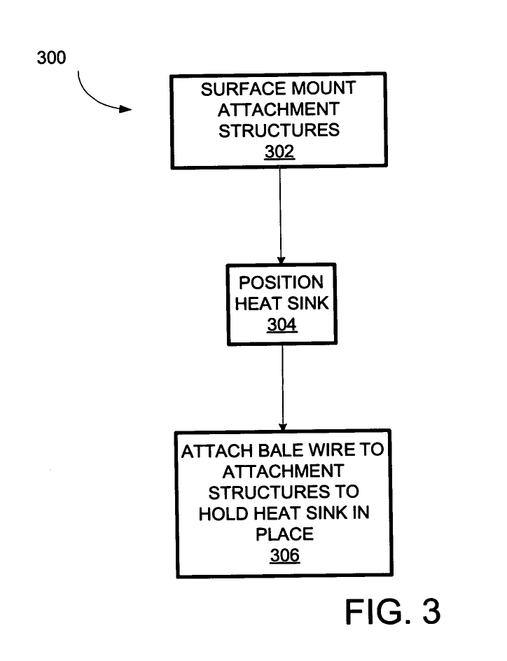

### DETAILED DESCRIPTION

The present invention uses surface-mount technology to fix attachment structures to a PC board. The attachment structures are used to attach a retention device that can extend over a heat sink or other object to secure its position over a PC board. Since the attachment structures are surface-mounted, no holes are required through the PC board, simplifying layout of its conductive layers.

A computer AP1 includes a processor 101, memory 103, and input/output devices 105. Processor 101 is mounted on a PC board 107. In practice, PC board 107 can be a daughterboard mounted on a motherboard of computer AP1. A heat sink 109 is mounted on processor 101 on the side of processor 101 opposite PC board 107. A layer of thermal grease 111 ensures good thermal contact between processor 101 and heat sink 109. In alternative embodiments, heat sinks or other objects can be mounted on voltage regulators or other heat-generating devices in accordance with the invention.

Surface mount pads 113 are provided on PC board 109 adjacent opposing sides of processor 101. Hooks 115 are soldered to these pads, with the hook ends directed away from processor 101. In alternative embodiments, the hooks have other orientations. The solder forms separate “islands” 117 rather than a continuous binding layer. Such islands are conventionally used for integrated circuit devices to maintain electrical isolation between connect pins. There is no such requirement for hooks 115, but the islands serve to prevent stress fractures from propagating across the hook base. Thus, a more reliable attachment is provided for hooks 115; this is important given that the hooks can be stressed by the heat sink mass. A bale wire 119 is attached to both hooks 115 so that it contacts heat sink 109, securing its position over processor 101. In alternative embodiments, another form of strap or another type of retention device is used instead of the bale wire.

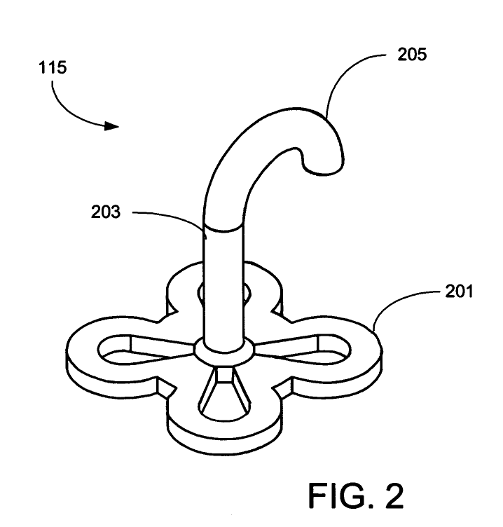

One of hooks 115 is shown in greater detail in FIG. 2. Hook 115 includes a base 201, a stem 203, and a curved end 205. Base 201 has a four-leaf design in which each leaf is open. This design provides ample surface area for solder to flow and attach. Of course, many other base designs are possible, including solid circular or square bases, with or without holes for solder to penetrate.

The present invention provides for a method 300 in which hooks or other attachment structures are surface mounted to a PC board at method segment 302. The hooks can be located and placed by current “pick and place” machinery and be secured by current solder attach methods. At method segment 304, a heat sink or other object is positioned, e.g., mounted on a processor. At method segment 306, a bale wire is attached to the attachment structures so that it contacts the heat sink and secures its position relative to the PC board.

The invention provides for many types of modifications. “Computer” herein encompasses not only general-purpose computers, but servers including multiprocessor servers, and various other devices that include embedded computers such as communications devices, appliances, medical devices, electronic “gadgets”, etc. The object to be attached can be a heat sink or any other object that needs to be attached to another object on a PC board. Where a heat sink is being attached, the underlying object can be a processor (single core or multicore), or other heat-generating integrated circuit, a power device, such as a voltage regulator, or an electro-magnetic interference (EMI) fence.

The attachment structures can be hooks, loops, or other formations suitable for attachment by a bale wire or other form of strap. Alternatively, a bridge can be formed between two, e.g., matching, solder pads. The attachment structure can be made of a single or multiple materials including metal and/or ceramic. For example, the hook can be entirely of metal, or the base and hook can be of different materials. The attachment structure can be of various heights, and diameters.

Additional hooks and straps can be used to further secure a heat sink or other object. For example, two straps (using two sets of hooks) can be arranged orthogonally to constrain movement parallel to the PC board. Also, additional hooks can provide parallel straps or wires for better securing a heat sink or other object. These and other variations upon and modifications to the illustrated embodiment are provided for by the present invention, the scope of which is defined by the following claims.

What is claimed is:

1. An assembly comprising:
a printed-circuit board;
an object disposed directly or indirectly on said PC board;
attachment mechanism surface-mounted to said PC board; and
a retention device attached to said attachment structures and extending across said object so as to secure its position on said PC board.

2. An assembly as recited in claim 1 wherein each of said attachment mechanisms are soldered to a metal pad on said PC board using plural islands of solder.

3. An assembly as recited in claim 1 wherein said attachment structures are hooks or loops.

4. An assembly as recited in claim 1 wherein said object is a heat sink.

5. An assembly as recited in claim 4 wherein said heat sink is positioned over a heat-generating device disposed directly or indirectly on said PC board.

6. An assembly as recited in claim 5 wherein said heat-generating device is a microprocessor, voltage regulator or an EMI fence.

7. A method comprising:
surface-mounting attachment means to a PC board;
securing an object relative to said PC board using a retention device attached to said attachment structures.

8. A method as recited in claim 7 wherein said surface-mounting involves soldering said attachment mechanisms to metal pads on said PC board using plural islands of solder.

9. A method as recited in claim 7 wherein said attachment structures are hooks or loops.

10. A method as recited in claim 7 wherein said object is a heat sink.

11. A method as recited in claim 10 wherein said heat sink is positioned over a heat-generating device disposed directly or indirectly on said PC board.

12. A method as recited in claim 11 wherein said heat-generating device is a microprocessor, voltage regulator or an EMI fence.
